(19) United States
(12) Patent Application Publication
(10) Pub. No.: US 2016/0276368 A1
(43) Pub. Date: Sep. 22, 2016

(54) Thin-Film Transistor Array Substrate And Method For Manufacturing Thin-Film Transistor Array Substrate

(71) Applicant: SHENZHEN CHINA STAR OPTOELECTRONICS TECHNOLOGY CO. LTD., Shenzhen, Guangdong (CN)

(72) Inventors: Li CHAI, Shenzhen, Guangdong (CN); Xiaoxing ZHANG, Shenzhen, Guangdong (CN)

(73) Assignee: Shenzhen China Star Optoelectronics Technology Co. Ltd., Shenzhen, Guangdong (CN)

(21) Appl. No.: 14/414,099

(22) PCT Filed: Sep. 16, 2014
(86) PCT No.: PCT/CN2014/086620

§ 371 Date: Jan. 10, 2015

(30) Foreign Application Priority Data
Sep. 10, 2014 (CN) 201410459799.0

(51) Int. Cl. H01L 27/12; H01L 23/532; H01L 21/66

(52) U.S. Cl. CPC H01L 27/124; H01L 27/1255; H01L 22/32; H01L 23/53204; H01L 27/1259

(57) ABSTRACT

A TFT array substrate and a method for manufacturing a TFT are disclosed. The TFT array substrate includes: a plurality of first metal lines, a first gap being formed between adjacent ones of the first metal lines; a plurality of second metal lines, a second gap being formed between adjacent ones of the second metal lines, the second metal lines and the first metal lines intersecting each other to form a plurality of overlapping sections; a first insulation layer arranged to stack between the first metal lines and the second metal lines to provide insulation between the first metal lines and the second metal lines; a second insulation layer set on and covering the second metal lines and arranged to stack on the second metal lines; and a transparent conductive film set on and covering the second insulation layer.

### CROSS REFERENCE TO RELATED APPLICATIONS

This application claims the priority of Chinese Patent Application No. 201410459799.0, entitled “Thin-Film Transistor Array Substrate and Method for Manufacturing Thin-Film Transistor Array Substrate”, filed on Sep. 10, 2014, the disclosure of which is incorporated herein by reference in its entirety.

### BACKGROUND OF THE INVENTION

1. Field of the Invention

The present invention relates to the field of liquid crystal displaying, and in particular to a thin-film transistor array substrate and a method for manufacturing a thin-film transistor array substrate.

2. The Related Arts

A thin-film transistor (TFT) array substrate is an important constituent component of a liquid crystal display. The TFT array substrate comprises a display zone on which a TFT array is arranged and a trace zone arranged to surround the display zone. Generally, the trace zone comprises a plurality of metal lines arranged therein. The metal lines have an end electrically connected to a test pad to receive a test signal and an opposite end of the metal lines electrically connected to TFTs within the display zone to transmit the test signal to the TFTs. In the prior art techniques, the plurality of metal lines is arranged in two layers and for easy description, the metal lines on the lower layer are referred to as first metal lines, while the metal lines on the upper layer are second metal lines. The second metal lines and the first metal lines are isolated from each other by a first insulation layer and the second metal lines and the first metal lines are arranged to intersect each other to form overlapping sections. The first metal lines are generally formed during a process of making gate terminals of the TFTs, while the second metal lines are generally formed during a process of making source terminals and drain terminals of the TFTs.

In a process of manufacturing a TFT array substrate, damages caused by electro-static discharge (ESD) often occur. The damages of the TFT array resulting from ESD may be caused by various factors. When ESD occurs in a TFT array substrate, it often needs to analyze the causes of the occurrence of the ESD on the TFT array substrate (for example determining which step of the manufacturing process causes the ESD on the TFT array substrate), in order to remove the causes that lead to the ESD. In the operations of five-mask manufacturing process for manufacturing a TFT array substrate, the manufacturing operations of each layer may have ESD. ESD occurring in the fourth layer manufacturing operation or the fifth layer manufacturing operation may often appear as damage to the overlapping sections between the second metal lines and the first metal lines. For an ESD damage of an TFT array substrate occurring in the fourth layer manufacturing operation or the fifth layer manufacturing operation, it is often hard to determine the ESD damage of the TFT array substrate is caused by which one of the fourth layer manufacturing operation or the fifth layer manufacturing operation.

### SUMMARY OF THE INVENTION

The present invention provides a thin-film transistor (TFT) array substrate, which, in case of an electro-static discharge (ESD) damage caused by a fourth layer manufacturing operation or a fifth layer manufacturing operation of the TFT array substrate, allows for identifying if the ESD damage of the TFT array substrate is caused by the fourth layer manufacturing operation or the fifth layer manufacturing operation.

In a first aspect, a thin-film transistor (TFT) array substrate is provided. The TFT array substrate comprises:

a plurality of first metal lines, a first gap being formed between adjacent ones of the first metal lines;

a plurality of second metal lines, a second gap being formed between adjacent ones of the second metal lines, the second metal lines and the first metal lines intersecting each other to form a plurality of overlapping sections;

a first insulation layer, which is stacked between the first metal lines and the second metal lines to provide insulation between the first metal lines and the second metal lines;

a second insulation layer, which is set on and covers the second metal lines and is arranged to stack on the second metal lines; and

a transparent conductive film, which is set on and covers the second insulation layer.

In a first embodiment of the first aspect, the TFT array substrate comprises a display zone in which a TFT array is arranged and a trace zone arranged to surround the display zone, the first metal lines and the second metal lines being arranged in the trace zone of the TFT array substrate.

In combination with the first embodiment of the first aspect, in a second embodiment of the first aspect, the first metal lines and the second metal lines are test lines of the TFT array substrate.

In a third embodiment of the first aspect, the array substrate comprises a display zone in which a TFT array is arranged and a trace zone arranged to surround the display zone, the first metal lines and the second metal lines being arranged in the display zone of the array substrate.

In combination with the third embodiment of the first aspect, in a fourth embodiment of the first aspect, the first metal lines are gate lines of TFTs and the second metal lines are data lines of the TFTs.

In a fifth embodiment of the first aspect, the transparent conductive film comprises a plurality of transparent conductive blocks, each of the transparent conductive blocks being arranged on the second insulation layer and stacked on each of the overlapping sections.

In a sixth embodiment of the first aspect, the transparent conductive film is an indium tin oxide film.

In a second aspect, a method for manufacturing a TFT array substrate is provided. The method for manufacturing the TFT array comprises:

providing a substrate;

forming a first metal layer on the substrate and patternizing the first metal layer to form a plurality of first metal lines in such a way that a first gap is formed between adjacent ones of the first metal lines;

providing a first insulation layer that is arranged to stack on the patternized first metal layer;

forming a second metal layer and patternizing the second metal layer to form a plurality of second metal lines in such a way that a second gap is formed between adjacent ones of the second metal lines and the second metal lines and the first metal lines intersect each other to form a plurality of overlapping sections;

providing a second insulation layer to cover the patternized second metal layer; and

providing a transparent conductive film, which is set on and covers the second insulation layer.

In a first embodiment of the second aspect, after the step of “providing a transparent conductive film, which is set on and covers the second insulation layer”, the method for manufacturing the TFT array substrate further comprises:

patternizing the transparent conductive film in such a way that the patternized transparent conductive film comprises a plurality of transparent conductive blocks and each of the transparent conductive blocks is arranged on the second insulation layer 140 and is stacked on and corresponding to an each of the overlapping sections.

In a third embodiment of the second aspect, the TFT array substrate comprises a display zone in which a TFT array is arranged and a trace zone arranged to surround the display zone, the first metal lines and the second metal lines being arranged in the trace zone of the TFT array substrate.

In combination with the third embodiment of the second aspect, in a fourth embodiment of the second aspect, the first metal lines and the second metal lines are test lines of the TFT array substrate.

In a fifth embodiment of the second aspect, between the step of “providing a first insulation layer that is arranged to stack on the patternized first metal layer” and the step of “forming a second metal layer and patternizing the second metal layer to form a plurality of second metal lines in such a way that a second gap is formed between adjacent ones of the second metal lines and the second metal lines and the first metal lines intersect each other to form a plurality of overlapping sections”, the method for manufacturing the TFT array substrate further comprises:

forming a semiconductor layer on the first insulation layer; and

patternizing the semiconductor layer to remove portions of the semiconductor layer that correspond to the first metal lines to have the semiconductor layer arranged to correspond to the gate zones; and

the step of “forming a second metal layer and patternizing the second metal layer to form a plurality of second metal lines in such a way that a second gap is formed between adjacent ones of the second metal lines and the second metal lines and the first metal lines intersect each other to form a plurality of overlapping sections” comprises:

forming a second metal layer on the patternized semiconductor layer and patternizing the second metal layer to form a plurality of second metal lines in such a way that a second gap is formed between adjacent ones of the second metal lines and the second lines and the first metal lines intersect each other to form a plurality of overlapping sections.

In combination with the fifth embodiment of the second aspect, in a sixth embodiment of the second aspect, the first metal lines are gate lines of TFTs and the second metal lines are data lines of the TFTs.

Compared to the prior art techniques, in a TFT array substrate and a method for manufacturing the TFT array substrate according to the present invention, a transparent conductive film is formed on a second insulation layer to correspond to overlapping sections formed on intersections of first metal lines and second metal lines so that it is possible, in respect of an ESD damage of the TFT array substrate caused by a fourth layer manufacturing operation or a fifth layer manufacturing operation, to identify if the ESD damage of the TFT array substrate is caused by the fourth layer manufacturing operation or the fifth layer manufacturing operation.

### BRIEF DESCRIPTION OF THE DRAWINGS

To more clearly explain the technical solution proposed in an embodiment of the present invention and that of the prior art, a brief description of the drawings that are necessary for describing embodiments is given as follows. It is obvious that the drawings that will be described below show only some embodiments. For those having ordinary skills of the art, other drawings may also be readily available from these attached drawings without the expense of creative effort and endeavor.

FIG. 1 is a schematic view showing a thin-film transistor (TFT) array substrate according to a preferred embodiment of the present invention;

FIG. 2 is an enlarged view of area A of FIG. 1 according to a preferred embodiment of the present invention;

FIG. 3 is an enlarged view of area I of FIG. 2 according to a preferred embodiment of the present invention;

FIG. 4 is a cross-sectional view taken along line II-II of FIG. 3 according to a preferred embodiment of the present invention;

FIG. 5 is a schematic view showing a TFT array substrate according to another preferred embodiment of the present invention;

FIG. 6 is an enlarged view of area A of FIG. 5 according to a preferred embodiment of the present invention;

FIG. 7 is an enlarged view of area III of FIG. 6 according to another preferred embodiment of the present invention;

FIG. 8 is a cross-sectional view taken along line IV-IV of FIG. 7 according to a preferred embodiment of the present invention;

FIG. 9 is a flow chart illustrating a method for manufacturing a TFT array substrate according to a preferred embodiment of the present invention; and

FIGS. 10-21 are cross-sectional views illustrating the TFT array substrate in various manufacturing steps of the method for manufacturing a TFT array substrate according to a preferred embodiment of the present invention.

### DETAILED DESCRIPTION OF THE PREFERRED EMBODIMENTS

A clear and complete description will be given to a technical solution of embodiments of the present invention with reference to the attached drawings of the embodiments of the present invention. However, the embodiments so described are only some, but not all, of the embodiments of the present invention. Other embodiments that are available to those having ordinary skills of the art without the expense of creative effort and endeavor are considered belonging to the scope of protection of the present invention.

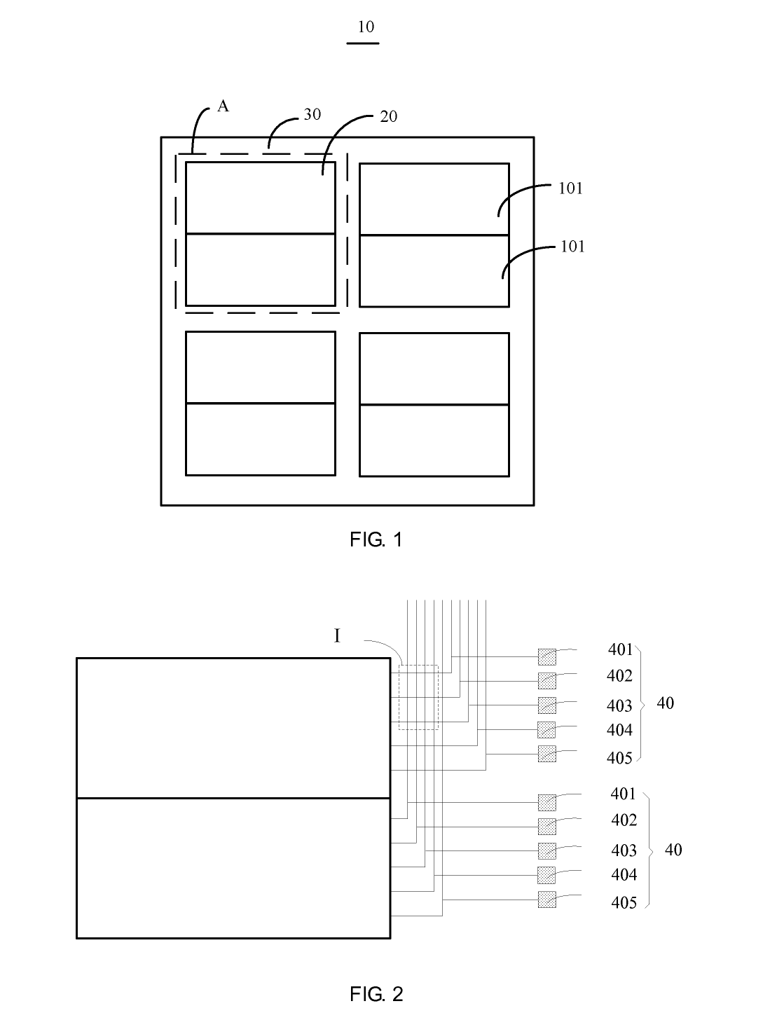

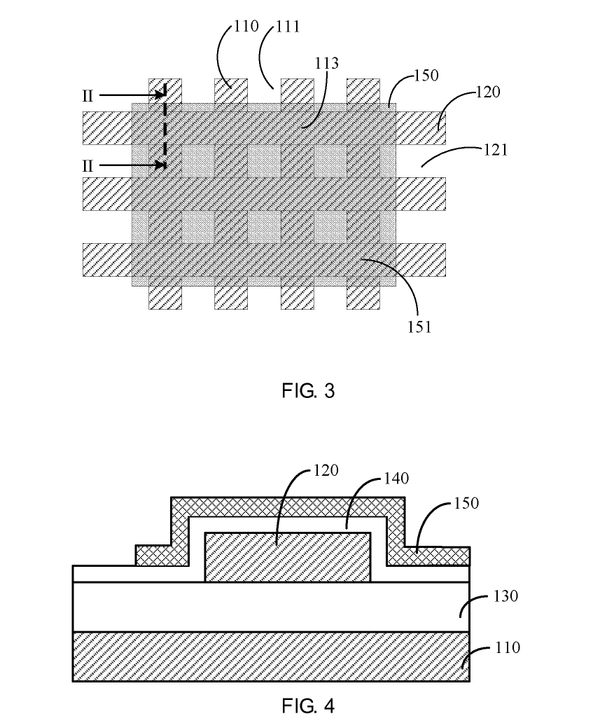

Referring collectively to FIGS. 1, 2, 3, and 4, FIG. 1 is a schematic view showing a thin-film transistor (TFT) array substrate according to a preferred embodiment of the present invention. FIG. 2 is an enlarged view of an area A of FIG. 1 according to a preferred embodiment of the present invention. FIG. 3 is an enlarged view of an area I of FIG. 2 according to a preferred embodiment of the present invention. FIG. 4 is a cross-sectional view taken along line II-II of FIG. 3 according to a preferred embodiment of the present invention. The TFT array substrate 10 comprises a plurality of first metal lines 110, a plurality of second metal lines 120, a first insulation layer 130, a second insulation layer 140, and a transparent conductive film 150. Adjacent ones of the first metal lines 110 define therebetween a first gap 111 so that the first gap 111 provides insulation between the two adjacent ones of the first metal lines 110. Adjacent ones of the second metal lines 120 define therebetween a second gap 121 and the second gap 121 provides insulation between the two adjacent ones of the second metal lines 120. The second metal lines 120 and the first metal lines 110 are arranged to intersect each other so as to form a plurality of overlapping sections 113. The first insulation layer 130 is arranged to stack between the first metal lines 110 and the second metal lines 120 to provide insulation between the first metal lines 110 and the second metal lines 120. The second insulation layer 140 is set on and covers the second metal lines 120 and is arranged to stack on the second metal lines 120. The transparent conductive film 150 is set on and covers the second insulation layer 140. The transparent conductive film 150 can be, but not limited to, an indium tin oxide (ITO) film.

Referring to FIG. 3, in the instant embodiment, the transparent conductive film 150 covers all the overlapping sections 113 and also covers remaining portions between the overlapping sections 113. In other words, the transparent conductive film 150 is a complete film that covers all gaps among the overlapping sections 113, the first metal lines 110, and the second metal lines 120, a portion of the first metal lines 110 between two adjacent ones of the overlapping sections 113, and a portion of the second metal lines 120 between two adjacent ones of the overlapping sections 113.

Referring again to FIGS. 1 and 2, as shown in FIG. 1, in manufacturing the TFT array substrate 10, it is often to form eight panels 101 on a glass substrate in such a way that every two panels 101 are arranged to be closely side by side to constitute a single unit A. The eight panels 101 collectively form an arrangement of a square with a cross in the interior thereof. The TFT array substrate 10 comprises a display zone 20 in which an TFT array is arranged and a trace zone 30 arranged to surround the display zone 20. The first metal lines 110 and the second metal lines 120 are arranged in the trace zone 30 of [symbol] the TFT array substrate 10. In the instant embodiment, the first metal lines 110 and the second metal lines 120 are test lines of the TFT array substrate 10. The TFT array substrate 10 further comprises a plurality of test pads 40. The test pads 40 are provided for receiving a test signal. The test pads 40 are electrically connected, via the first metal lines 110 and the second metal lines 120, to data lines and gate lines within the display zone 20 in order to transmit the received test signal to the data lines and the gate lines. In other words, an end of the first metal lines 110 and an end of the second metal lines 120 are respectively connected to the data lines and the gate lines within the display zone 20 of the TFT array substrate 10 and an opposite end of the first metal lines 110 and an opposite end of the second metal lines 120 are electrically connected with the test pads 40 to receive the test signal transmitted through the test pads 40. In the instant embodiment, the test pads 40 each comprise five sub-test pads and for easy description, the five sub-test pads are respectively referred to as a first sub-test pad 401, a second sub-test pad 402, a third sub-test pad 403, a fourth sub-test pads 404, and a fifth sub-test pad 405. The first sub-test pad 401 is a common test pad (Array com test pad); the second sub-test pad 402 is an even data line test pad (Array data_Even test pad); the third sub-test pad 403 is an odd data line test pad (Array data_Odd test pad); the fourth sub-test pads 404 is an even gate line test pad (Array gate_Even test pad); and the fifth sub-test pad 405 is an odd gate line test pad (Array gate_Odd test pad).

It is appreciated that the first metal lines 110 and the second metal lines 120 are not limited to being arranged within the trace zone 30 of the TFT array substrate 10. The first metal lines 110 and the second metal lines 120 are not limited to test lines. In another embodiment, the first metal lines 110 and the second metal lines 120 are, alternatively, arranged in the display zone 20 of the TFT array substrate 10. When the first metal lines 110 and the second metal lines 120 are arranged in the display zone 20 of the TFT array substrate 10, the first metal lines 110 can be the gate lines of TFTs and the second metal lines 120 can be data lines of TFTs.

It is appreciated that although an example involving the area I is taken for illustration in FIG. 1, the overlapping sections 113 are not limited to being within the area I and can alternatively be within other locations where the first metal lines 120 and the second metal lines 130 stack each other.

In a manufacturing process of the TFT array substrate 10, the second insulation layer 140 is formed by a fourth layer manufacturing operation of a fifth masking operation and the transparent conductive film 150 is formed by a fifth layer manufacturing operation of a fifth manufacturing operation. In the prior art techniques, in a manufacturing process of the TFT array substrate 10, the transparent conductive film 150, after being formed, is subjected to patternizing in order to completely remove the portion of the transparent conductive film 150 within the trace zone 30 and only the portions of the transparent conductive film 150 that correspond to drain zones of the TFTs are kept. The portions of the transparent conductive film 150 corresponding to the drain terminals of the TFTs are electrically connected through vias to the drain zones of the TFTs. Compared to the prior art techniques, in the present invention, the first metal lines 110 and the second metal lines 120 of the trace zone 30 of the TFT array substrate 10 are arranged to intersect each other thereby forming a plurality of overlapping sections 113. The plurality of overlapping sections 113 is provided thereon with the transparent conductive film 150. When electro-static discharge (ESD) occurs in the second insulation layer 140, but the transparent conductive film 150 remain intact, then ESD is identified to be caused by the fourth manufacturing operation of the TFT array substrate 10. When the second insulation layer 140 is intact, but the transparent conductive film 150 remains intact, the ESD damage of the TFT array substrate 10 is identified as being caused by the fifth manufacturing operation.

Specifically, determining if the second insulation layer 140 or the transparent conductive film 150 is intact can be achieved with the following process. A scanning electron microscope (SEM) is used to scan a surface of the TFT array substrate 10 to obtain surface structures of the second insulation layer 140 and the transparent conductive film 150 of the TFT array substrate 10 in order to determine if the second insulation layer 140 and the transparent conductive film 150 are intact. Since the second insulation layer 140 and the transparent conductive film 150 are made of different materials, the lattice structure of the second insulation layer 140 and the lattice structure of the transparent conductive film 150 are different. The SEM may distinguish the second insulation layer 140 and the transparent conductive film 150 from each other according to the lattice structures obtained through scanning the surface of the TFT array substrate 10, and may determine if the second insulation layer 140 is intact according to if the lattice structure of the second insulation layer 140 is intact, and may determine if the transparent conductive film 150 is intact according to if the lattice structure of the transparent conductive film 150 is intact. Specifically, the process of determining if the second insulation layer 140 is intact according to if the lattice structure of the second insulation layer 140 is intact is described as follows. When the lattice structure of the second insulation layer 140 is damaged (such as breaking being found in the lattice structure that is supposed to be continuous), it is determined that ESD occurs in the second insulation layer 140; when the lattice structure of the second insulation layer 140 is intact, it is determined no ESD occurs in the second insulation layer 140, meaning the second insulation layer 140 is intact. Similarly, the process of determining if the transparent conductive film 150 is intact according to if the lattice structure of the transparent conductive film 150 is intact is described as follows. When the lattice structure of the transparent conductive film 150 is damaged (such as breaking being found in the lattice structure that is supposed to be continuous), it is determined that ESD occurs in the transparent conductive film 150; when the lattice structure of the transparent conductive film 150 is intact, it is determined no ESD occurs in the transparent conductive film 150, meaning the transparent conductive film 150 is intact.

It is understood from the above description that, compared to the prior art techniques, in the manufacturing operation of the TFT array substrate, since the transparent conductive film 150 is provided on the second insulation layer 140 to correspond to the overlapping sections 113 formed by the intersections of the first metal lines 110 and the second metal lines 120, it is possible, in respect of ESD damages of the TFT array substrate caused by the fourth layer manufacturing operation or the fifth layer manufacturing operation, to tell if the ESD damages of the TFT array substrate are caused by the fourth layer manufacturing operation or the fifth layer manufacturing operation.

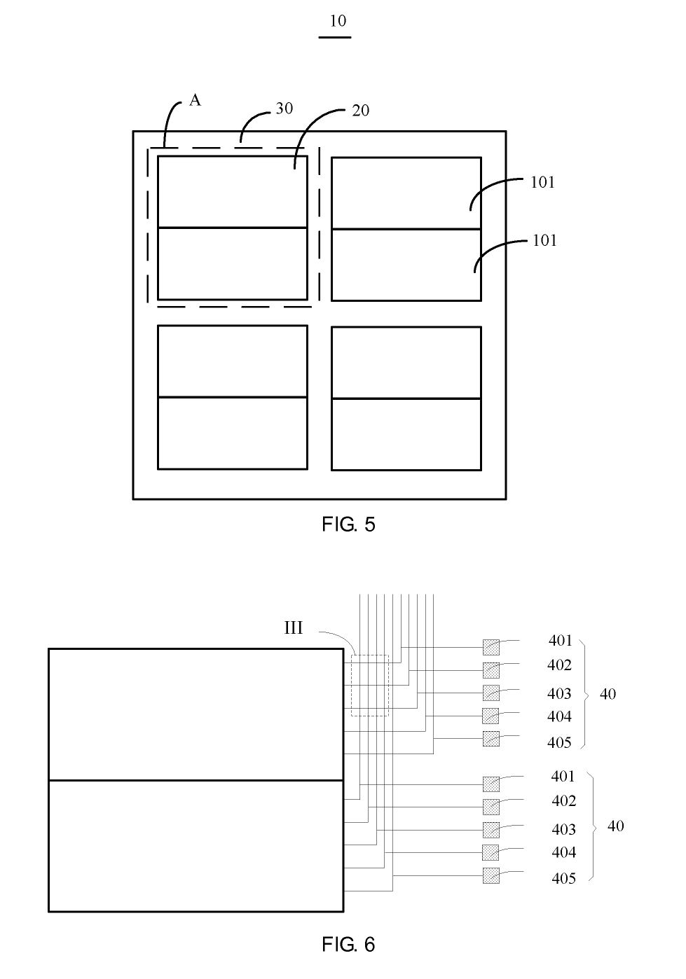

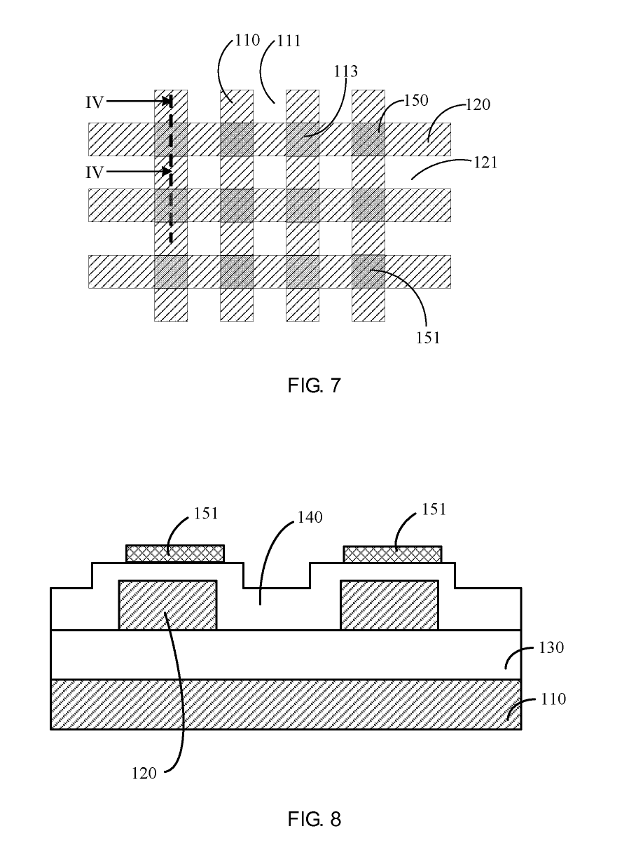

Referring collectively to FIGS. 5, 6, 7, and 8, FIG. 5 is a schematic view showing a TFT array substrate according to another preferred embodiment of the present invention. FIG. 6 is an enlarged view of an area A of FIG. 5 according to a preferred embodiment of the present invention. FIG. 7 is an enlarged view of an area III of FIG. 6 according to another preferred embodiment of the present invention. FIG. 8 is a cross-sectional view taken along line IV-IV of FIG. 7 according to a preferred embodiment of the present invention. The TFT array substrate 10 comprises a plurality of first metal lines 110, a plurality of second metal lines 120, a first insulation layer 130, a second insulation layer 140, and a transparent conductive film 150. Adjacent ones of the first metal lines 110 define therebetween a first gap 111 so that the first gap 111 provides insulation between the two adjacent ones of the first metal lines 110. Adjacent ones of the second metal lines 120 define therebetween a second gap 121 and the second gap 121 provides insulation between the two adjacent ones of the second metal lines 120. The second metal lines 120 and the first metal lines 110 are arranged to intersect each other so as to form a plurality of overlapping sections 113. The first insulation layer 130 is arranged to stack between the first metal lines 110 and the second metal lines 120 to provide insulation between the first metal lines 110 and the second metal lines 120. The second insulation layer 140 is set on and covers the second metal lines 120 and is arranged to stack on the second metal lines 120. The transparent conductive film 150 is set on and covers the second insulation layer 140. The transparent conductive film 150 can be, but not limited to, an indium tin oxide (ITO) film.

Referring again to FIGS. 7 and 8, in the instant embodiment, the transparent conductive film 150 comprises a plurality of transparent conductive blocks 151. Each of the transparent conductive blocks 151 is arranged on the second insulation layer 140 and is arranged to stack on each of the overlapping sections 113.

Referring again to FIG. 5, as shown in FIG. 5, in manufacturing the TFT array substrate 10, it is often to form eight panels 101 on a glass substrate in such a way that every two panels 101 are arranged to be closely side by side to constitute a single unit A. The eight panels 101 collectively form an arrangement of a square with a cross in the interior thereof. The TFT array substrate 10 comprises a display zone 20 in which an TFT array is arranged and a trace zone 30 arranged to surround the display zone 20. The first metal lines 110 and the second metal lines 120 are arranged in the trace zone 30 of [symbol] the TFT array substrate 10. In the instant embodiment, the first metal lines 110 and the second metal lines 120 are test lines of the TFT array substrate 10. The TFT array substrate 10 further comprises a plurality of test pads 40. The test pads 40 are provided for receiving a test signal. The test pads 40 are electrically connected, via the first metal lines 110 and the second metal lines 120, to data lines and gate lines within the display zone 20 in order to transmit the received test signal to the data lines and the gate lines. In other words, an end of the first metal lines 110 and an end of the second metal lines 120 are respectively connected to the data lines and the gate lines within the display zone 20 of the TFT array substrate 10 and an opposite end of the first metal lines 110 and an opposite end of the second metal lines 120 are electrically connected with the test pads 40 to receive the test signal transmitted through the test pads 40. In the instant embodiment, the test pads 40 each comprise five sub-test pads and for easy description, the five sub-test pads are respectively referred to as a first sub-test pad 401, a second sub-test pad 402, a third sub-test pad 403, a fourth sub-test pads 404, and a fifth sub-test pad 405. The first sub-test pad 401 is a common test pad (Array com test pad); the second sub-test pad 402 is an even data line test pad (Array data_Even test pad); the third sub-test pad 403 is an odd data line test pad (Array data_Odd test pad); the fourth sub-test pads 404 is an even gate line test pad (Array gate_Even test pad); and the fifth sub-test pad 405 is an odd gate line test pad (Array gate_Odd test pad).

It is appreciated that the first metal lines 110 and the second metal lines 120 are not limited to being arranged within the trace zone 30 of the TFT array substrate 10. The first metal lines 110 and the second metal lines 120 are not limited to test lines. In other embodiments, the first metal lines 110 and the second metal lines 120 are, alternatively, arranged in the display zone 20 of the TFT array substrate 10. When the first metal lines 110 and the second metal lines 120 are arranged in the display zone 20 of the TFT array substrate 10, the first metal lines 110 can be the gate lines of TFTs and the second metal lines 120 can be data lines of TFTs.

In a manufacturing process of the TFT array substrate 10, the second insulation layer 140 is formed by a fourth layer manufacturing operation of a fifth masking operation and the transparent conductive film 150 is formed by a fifth layer manufacturing operation of a fifth manufacturing operation. In the prior art techniques, in a manufacturing process of the TFT array substrate 10, the transparent conductive film 150, after being formed, is subjected to patternizing in order to completely remove the portion of the transparent conductive film 150 within the trace zone 30 and only the portions of the transparent conductive film 150 that correspond to drain zones of the TFTs are kept. The portions of the transparent conductive film 150 corresponding to the drain terminals of the TFTs are electrically connected through vias to the drain zones of the TFTs. Compared to the prior art techniques, in the present invention, the first metal lines 110 and the second metal lines 120 of the trace zone 30 of the TFT array substrate 10 are arranged to intersect each other thereby forming a plurality of overlapping sections 113. The plurality of overlapping sections 113 is provided thereon with the transparent conductive film 150. When electro-static discharge (ESD) occurs in the second insulation layer 140, but the transparent conductive film 150 remain intact, then ESD is identified to be caused by the fourth manufacturing operation of the TFT array substrate 10. When the second insulation layer 140 is intact, but the transparent conductive film 150 remains intact, the ESD damage of the TFT array substrate 10 is identified as being caused by the fifth manufacturing operation.

Specifically, determining if the second insulation layer 140 or the transparent conductive film 150 is intact can be achieved with the following process. A scanning electron microscope (SEM) is used to scan a surface of the TFT array substrate 10 to obtain surface structures of the second insulation layer 140 and the transparent conductive film 150 of the TFT array substrate 10 in order to determine if the second insulation layer 140 and the transparent conductive film 150 are intact. Since the second insulation layer 140 and the transparent conductive film 150 are made of different materials, the lattice structure of the second insulation layer 140 and the lattice structure of the transparent conductive film 150 are different. The SEM may distinguish the second insulation layer 140 and the transparent conductive film 150 from each other according to the lattice structures obtained through scanning the surface of the TFT array substrate 10, and may determine if the second insulation layer 140 is intact according to if the lattice structure of the second insulation layer 140 is intact, and may determine if the transparent conductive film 150 is intact according to if the lattice structure of the transparent conductive film 150 is intact. Specifically, the process of determining if the second insulation layer 140 is intact according to if the lattice structure of the second insulation layer 140 is intact is described as follows. When the lattice structure of the second insulation layer 140 is damaged (such as breaking being found in the lattice structure that is supposed to be continuous), it is determined that ESD occurs in the second insulation layer 140; when the lattice structure of the second insulation layer 140 is intact, it is determined no ESD occurs in the second insulation layer 140, meaning the second insulation layer 140 is intact. Similarly, the process of determining if the transparent conductive film 150 is intact according to if the lattice structure of the transparent conductive film 150 is intact is described as follows. When the lattice structure of the transparent conductive film 150 is damaged (such as breaking being found in the lattice structure that is supposed to be continuous), it is determined that ESD occurs in the transparent conductive film 150; when the lattice structure of the transparent conductive film 150 is intact, it is determined no ESD occurs in the transparent conductive film 150, meaning the transparent conductive film 150 is intact.

It can be seen that compared to the prior art techniques, in the manufacturing operation of the TFT array substrate, for an ESD damage of the TFT array substrate caused by the fourth layer manufacturing operation or the fifth layer manufacturing operation, since the transparent conductive film 150 is arranged on the overlapping sections 113 formed by the intersections of the first metal lines 110 and the second metal lines 120, it is possible to tell if the ESD damage of the TFT array substrate is caused by the fourth layer manufacturing operation or the fifth layer manufacturing operation.

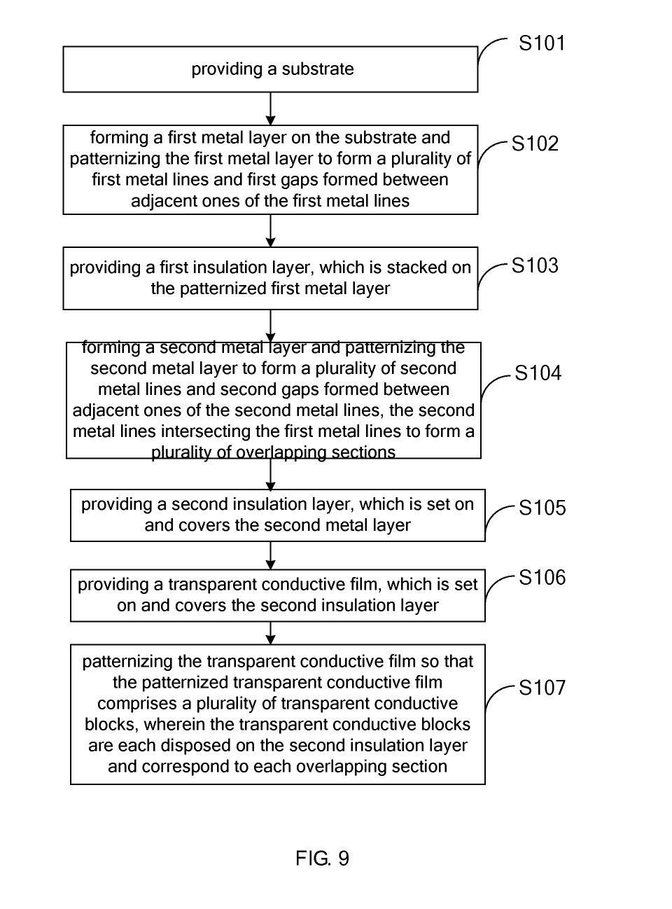

A method for manufacturing a TFT array substrate will be described with reference to FIGS. 1-8. Additional reference being had to FIG. 9, FIG. 9 is a flow chart illustrating a method for manufacturing a TFT array substrate according to a preferred embodiment of the present invention. The method for manufacturing a TFT array substrate 10 comprises the following steps.

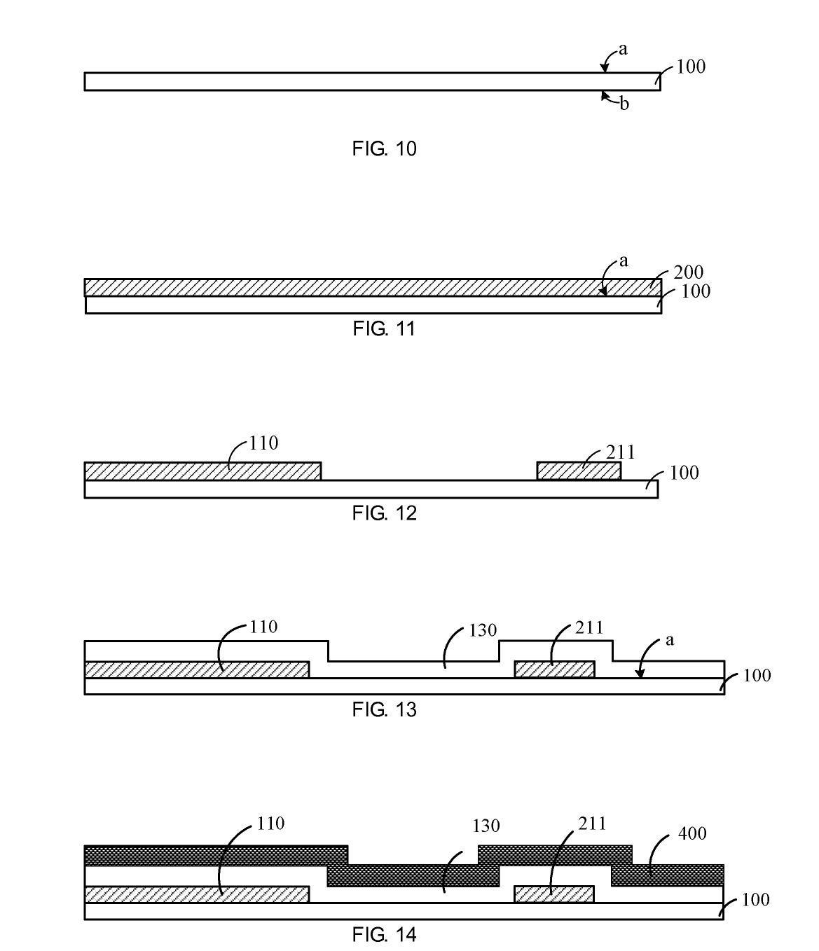

Step S101: providing a substrate 100. With additional reference to FIG. 10, the substrate 100 comprises a first surface a and a second surface b opposite to the first surface a. In the instant embodiment, the substrate 100 is a glass substrate. It is appreciated that, in other embodiments, the substrate 100 may not be limited to a glass substrate.

Step S102: forming a first metal layer 200 on the substrate 100 and patternizing the first metal layer 200 to form a plurality of first metal lines 110 in such a way that a first gap 111 is formed between adjacent ones of the first metal lines 110. The material of the first metal layer 200 is selected from one of copper, tungsten, chromium, aluminum, and combinations thereof. With additional reference to FIG. 11, the first metal layer 200 is formed on the first surface a of the substrate 100. In other embodiments, the first metal layer 200 may alternatively be formed on the second surface b of the substrate 100. With additional reference to FIG. 12, in the instant embodiment, the first metal layer 200 is patternized to form a plurality of first metal lines 110 and also forming a gate zone 211 of a TFT 21. FIG. 12 only shows one first metal line 110 and only shows, in a schematic form, one gate zone 211. Patternizing the first metal layer 200 forms a plurality of first metal lines 110 and a plurality of gate zones 211 and at the same time, the first surface a of the substrate 100 is exposed.

Step S103: providing a first insulation layer 130 that is arranged to stack on the patternized first metal layer 200. With additional reference to FIG. 13, the first insulation layer 130 is formed on the first metal lines 110, the gate zones 211, and the portion of the first surface a that is not covered by the first metal lines 110 and the gate zone 211. The material of the first insulation layer is selected from one of silicon oxides, silicon nitrides, silicon oxynitrides, and combinations thereof.

Between Step S103 and Step S104, the following steps are further included:

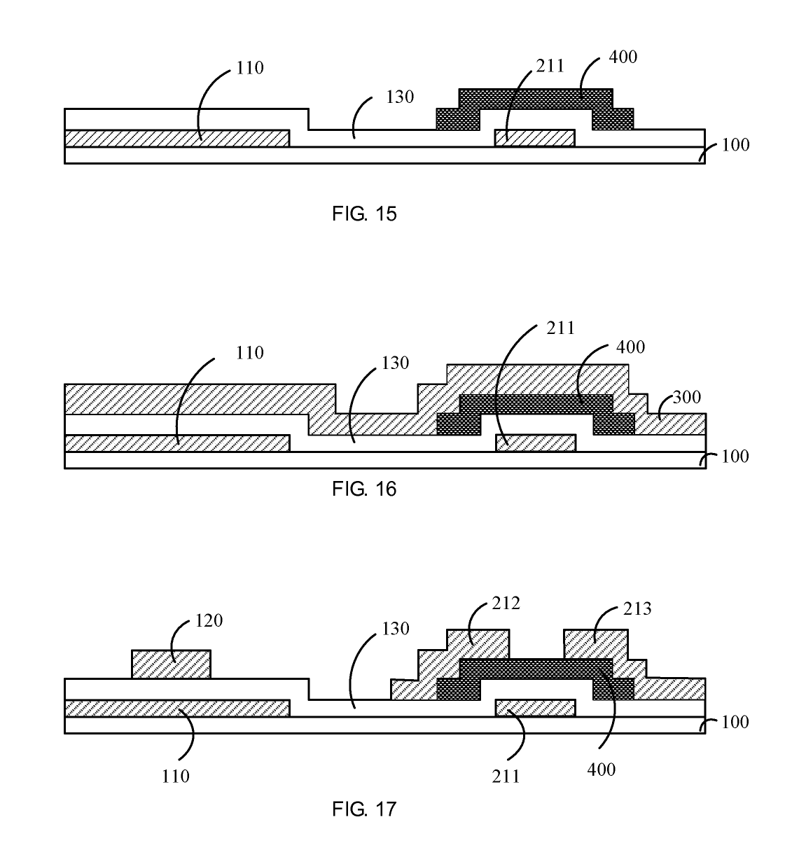

Step A: forming a semiconductor layer 400 on the first insulation layer 130. With additional reference to FIG. 14, the semiconductor layer 400 and the first insulation layer 130 are arranged to stack on each other. Step B: patternizing the semiconductor layer 400 to remove portions of the semiconductor layer 400 that correspond to the first metal lines 110 to have the semiconductor layer 400 stacked on and corresponding to the gate zones 211. With additional reference to FIG. 15, the semiconductor layer 400 is patternized in such a way as to be only stacked on the gate zones 211.

Step S104: forming a second metal layer 300 and patternizing the second metal layer 300 to form a plurality of second metal lines 120 in such a way that a second gap 121 is formed between adjacent ones of the second metal lines 120 and the second metal lines 120 and the first metal lines 110 intersect each other to form a plurality of overlapping sections 113. With additional reference to FIG. 16, the second metal layer 300 is formed to stack on the patternized semiconductor layer 400 and a portion of the second insulation layer 140 that is not covered by the semiconductor layer 400. Step S104 specifically comprises: forming a second metal layer 300 on the patternized semiconductor layer 400 and patternizing the second metal layer 300 to form a plurality of second metal lines 120 in such a way that a second gap 121 is formed between adjacent ones of the second metal lines 120 and the second metal lines 120 and the first metal lines 110 intersect each other to form a plurality of overlapping sections 113. The material of the second metal layer 300 may also be selected from one of copper, tungsten, chromium, aluminum, and combinations thereof. With additional reference to FIG. 17, the second metal layer 300 is patternized to form a plurality of second metal lines 120. In the instant embodiment, patternizing the second metal layer 300 to form the second metal lines 120 also, at the same time, form a source zone 212 and a drain zone 214 of the TFT 21.

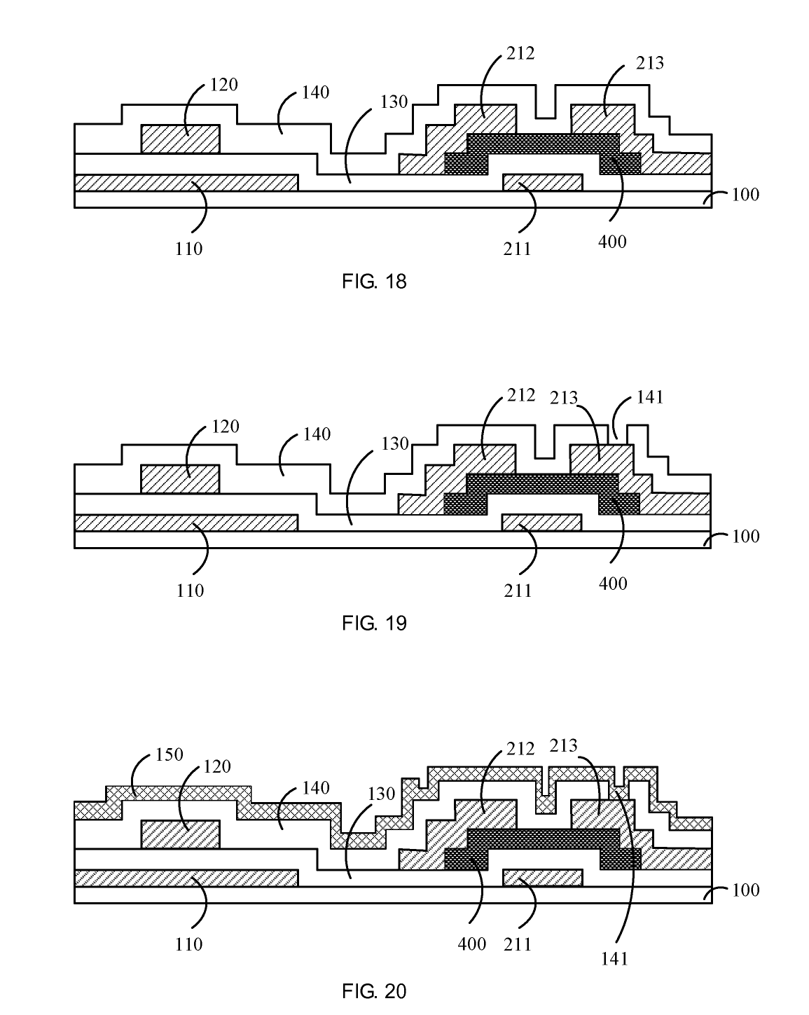

Step S105: providing a second insulation layer 140 to cover the patternized second metal layer 300. With additional reference to FIG. 18, the material of the first insulation layer may be selected from one of silicon oxides, silicon nitrides, silicon oxynitrides, and combinations thereof.

Between Step S105 and Step S106, Step C is further included:

A via 141 is formed in the second insulation layer 140 to correspond to the drain zone 214. With additional reference to FIG. 19, the via 141 is formed in the second insulation layer 140 to correspond to the drain zone 214 in order to partly expose the drain zone 214.

Step S106: providing a transparent conductive film 150, which is set on and covers the second insulation layer 140. With additional reference to FIG. 20, the transparent conductive film 150 is arranged to stack on the second insulation layer 140 and in the via 141.

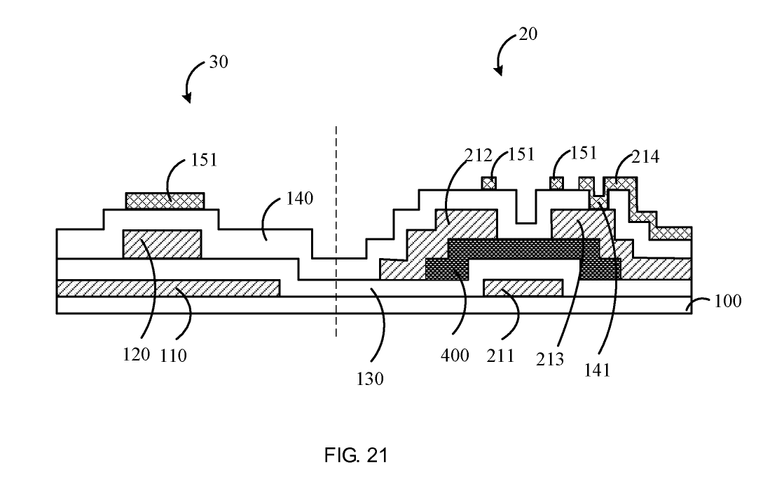

Step S107: patternizing the transparent conductive film 150 in such a way that the patternized transparent conductive film 150 comprises a plurality of transparent conductive blocks 151 and each of the transparent conductive blocks 151 is arranged on the second insulation layer 140 and corresponds to each of the overlapping sections 113. With additional reference to FIG. 21, in the instant embodiment, patternizing the transparent conductive film 150 to form the plurality of transparent conductive blocks 151 also and simultaneously forms a drain terminal 214. The drain terminal 214 is electrically connected to the drain zone 213. The first metal lines 110 and the second metal lines 120 are located in the trace zone 30 of the TFT array substrate 10. The TFT (the portion on right hand side of the phantom line of FIG. 21) is located in the trace zone 20.

It can be seen from the above description that the method for manufacturing the TFT array substrate 10 forms the transparent conductive film 150 on the second insulation layer 140 to correspond to the overlapping sections 113 formed on the intersections of the first metal lines 110 and the second metal lines 120 so that it is possible, in respect of an ESD damage of the TFT array substrate caused by the fourth layer manufacturing operation or the fifth layer manufacturing operation, to identify if the ESD damage of the TFT array substrate is caused by the fourth layer manufacturing operation or the fifth layer manufacturing operation.

Disclosed above is only one preferred embodiment of the present invention, which does not impose undue constraints to the scope of protection of the present invention. Those having ordinary skills of the art may readily appreciate that equivalent modifications that allow for realization of all or part of the operation process of the preferred embodiment described above and comply with the requirement defined in the appended claims are considered within the protection scope covered by the present invention.

What is claimed is:

1. A thin-film transistor (TFT) array substrate, comprising:
a plurality of first metal lines, a first gap being formed between adjacent ones of the first metal lines;
a plurality of second metal lines, a second gap being formed between adjacent ones of the second metal lines, the second metal lines and the first metal lines intersecting each other to form a plurality of overlapping sections;
a first insulation layer, which is stacked between the first metal lines and the second metal lines to provide insulation between the first metal lines and the second metal lines;
a second insulation layer, which is set on and covers the second metal lines and is arranged to stack on the second metal lines; and
a transparent conductive film, which is set on and covers the second insulation layer.

2. The TFT array substrate as claimed in claim 1, wherein the TFT array substrate comprises a display zone in which a TFT array is arranged and a trace zone arranged to surround the display zone, the first metal lines and the second metal lines being arranged in the trace zone of the TFT array substrate.

3. The TFT array substrate as claimed in claim 2, wherein the first metal lines and the second metal lines are test lines of the TFT array substrate.

4. The TFT array substrate as claimed in claim 1, wherein the array substrate comprises a display zone in which a TFT array is arranged and a trace zone arranged to surround the display zone, the first metal lines and the second metal lines being arranged in the display zone of the array substrate.

5. The TFT array substrate as claimed in claim 4, wherein the first metal lines are gate lines of TFTs and the second metal lines are data lines of the TFTs.

6. The TFT array substrate as claimed in claim 1, wherein the transparent conductive film comprises a plurality of transparent conductive blocks, each of the transparent conductive blocks being arranged on the second insulation layer and stacked on each of the overlapping sections.

7. The TFT array substrate as claimed in claim 1, wherein the transparent conductive film is an indium tin oxide film.

8. A method for manufacturing a thin-film transistor (TFT) array substrate, comprising:
providing a substrate;
forming a first metal layer on the substrate and patternizing the first metal layer to form a plurality of first metal lines in such a way that a first gap is formed between adjacent ones of the first metal lines;
providing a first insulation layer that is arranged to stack on the patternized first metal layer;
forming a second metal layer and patternizing the second metal layer to form a plurality of second metal lines in such a way that a second gap is formed between adjacent ones of the second metal lines and the second metal lines and the first metal lines intersect each other to form a plurality of overlapping sections;
providing a second insulation layer to cover the patternized second metal layer; and
providing a transparent conductive film, which is set on and covers the second insulation layer.

9. The method for manufacturing the TFT array substrate as claimed in claim 8, wherein after the step of “providing a transparent conductive film, which is set on and covers the second insulation layer”, the method for manufacturing the TFT array substrate further comprises:
patternizing the transparent conductive film in such a way that the patternized transparent conductive film comprises a plurality of transparent conductive blocks and each of the transparent conductive blocks is arranged on the second insulation layer 140 and is stacked on and corresponding to an each of the overlapping sections.

10. The method for manufacturing the TFT array substrate as claimed in claim 8, wherein the TFT array substrate comprises a display zone in which a TFT array is arranged and a trace zone arranged to surround the display zone, the first metal lines and the second metal lines being arranged in the trace zone of the TFT array substrate.

11. The method for manufacturing the TFT array substrate as claimed in claim 10, wherein the first metal lines and the second metal lines are test lines of the TFT array substrate.

12. The method for manufacturing the TFT array substrate as claimed in claim 8, wherein between the step of “providing a first insulation layer that is arranged to stack on the patternized first metal layer” and the step of “forming a second metal layer and patternizing the second metal layer to form a plurality of second metal lines in such a way that a second gap is formed between adjacent ones of the second metal lines and the second metal lines and the first metal lines intersect each other to form a plurality of overlapping sections”, the method for manufacturing the TFT array substrate further comprises:
forming a semiconductor layer on the first insulation layer; and
patternizing the semiconductor layer to remove portions of the semiconductor layer that correspond to the first metal lines to have the semiconductor layer arranged to correspond to the gate zones; and
the step of “forming a second metal layer and patternizing the second metal layer to form a plurality of second metal lines in such a way that a second gap is formed between adjacent ones of the second metal lines and the second metal lines and the first metal lines intersect each other to form a plurality of overlapping sections” comprises:
forming a second metal layer on the patternized semiconductor layer and patternizing the second metal layer to form a plurality of second metal lines in such a way that a second gap is formed between adjacent ones of the second metal lines and the second lines and the first metal lines intersect each other to form a plurality of overlapping sections.

13. The method for manufacturing the TFT array substrate as claimed in claim 12, wherein the first metal lines are gate lines of TFTs and the second metal lines are data lines of the TFTs.
